(19) United States
(12) Patent Application Publication
(10) Pub. No.: US 2025/0179902 A1
(43) Pub. Date: Jun. 5, 2025

(54) INTELLIGENT ADDITIVE DOSING IN HYDRAULIC FRACTURING

(71) Applicant: Halliburton Energy Services, Inc., Houston, TX (US)

(72) Inventors: Chaitanya Mallikaraj Karale, Houston, TX (US); Elijah Sterling Bogle, Houston, TX (US)

(21) Appl. No.: 18/529,952

(22) Filed: Dec. 5, 2023

(51) Int. Cl. E21B 43/26; E21B 47/00

(52) U.S. Cl. CPC E21B 43/2607; E21B 47/00; G06F 30/20; E21B 2200/20

(57) ABSTRACT

Some implementations include a method comprising: systematically changing a first value of one or more controllable variables used in a wellbore treatment operation; monitoring a value of a first operation parameter in response to systematically changing the first value of the one or more controllable variables; building at least a first relationship between the one or more controllable variables, the first operation parameter, and one or more cost functions; selecting a second value of the one or more controllable variables based on an optimized cost function; and adjusting the wellbore treatment operation based, at least in part, on the second value of the one or more controllable variables.

### FIELD

Some implementations relate generally to hydraulic fracturing a wellbore drilled into the subsurface, more particularly, to the field of automation in fracturing or any injection operations.

### BACKGROUND

During hydraulic fracturing and well treatment operations, the evaluation of job data and determining of set points for additive concentrations are traditionally performed manually. Additive concentration adjustments and changes to injection procedures are traditionally performed via manual operation, and these adjustments may be less than optimal. Crews at the surface may rely on prior knowledge and iterative adjustments to reach desired additive concentrations.

Rather than adjusting surface equipment (e.g., pumps, valves, etc.) to meet the set points, the additives may be introduced into the wellbore at specific concentrations to alter the injection of fluid into the well. For example, hydraulic horsepower (HHP) is a key component in multistage fracturing, as treatments are pumped at very high pressures (˜10,000 psi) and injection rates (100 barrels per minute (bpm)). By controlling, for example, the wellbore friction, perforation friction, tortuosity friction, proppant carrying capacity, etc. via one or more additives (i.e., friction reducers), the HHP may be lowered without compromising the injection rate. However, given a plurality of potential friction reducers (FRs) to use, discrepancies in water quality between sites, and discrepancies in total dissolved solids (TDS) between wells, it has traditionally been impractical to create a mathematical model to control HHP or determine an optimum additive concentration to maintain a desirable wellbore friction.

### BRIEF DESCRIPTION OF THE DRAWINGS

Implementations of the disclosure may be better understood by referencing the accompanying drawings.

FIG. 1 is a block diagram illustrating a fracturing spread configured for hydraulically fracturing subsurface formations in one or more wells, according to some implementations.

FIG. 2 is an illustration of treatment execution, according to some implementations.

FIG. 3 is a plot depicting a relationship between the additive concentration and treating pressure, according to some implementations.

FIG. 4 is an illustration depicting an example treatment execution including predicted treating pressures, according to some implementations.

FIG. 5 is a plot depicting a plurality of objective functions, according to some implementations.

FIG. 6 is a flowchart depicting example operations for real-time model building and additive concentration optimization and new decision execution, according to some implementations.

FIG. 7 is a plot depicting calibration adjustments that factor in slurry rate and proppant concentration, according to some implementations.

FIG. 8 is a block diagram depicting an example computer, according to some implementations.

FIG. 9 is a flowchart of an example method for optimizing one or more controllable variables for use in a wellbore treatment operation, according to some implementations.

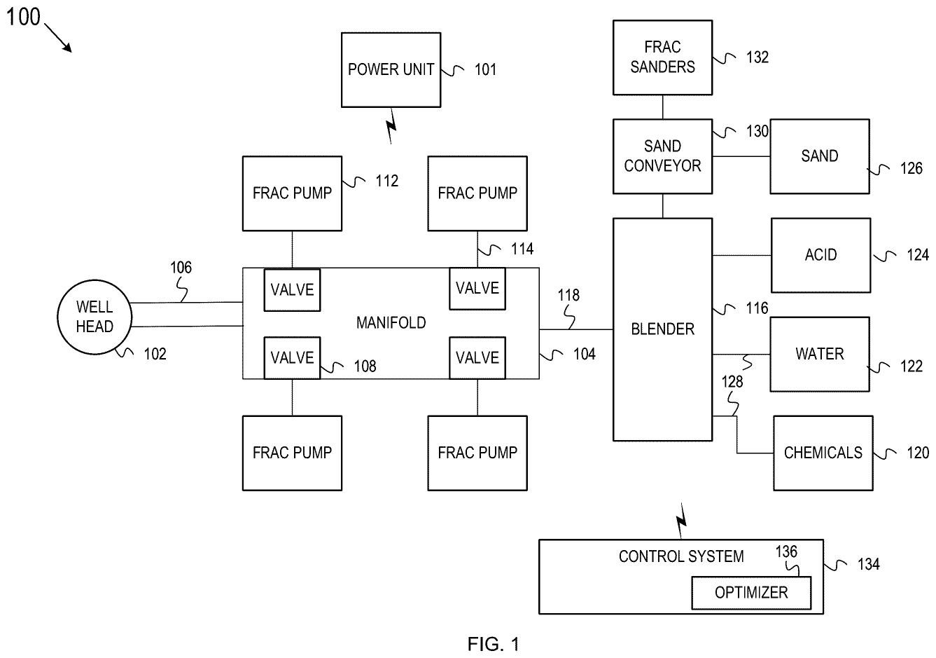

FIGS. 1-9 and the operations described herein are examples meant to aid in understanding example implementations and should not be used to limit the potential implementations or limit the scope of the claims. None of the implementations described herein may be performed exclusively in the human mind nor exclusively using pencil and paper. None of the implementations described herein may be performed without computerized components such as those described herein. Some implementations may perform additional operations, fewer operations, operations in parallel or in a different order, and some operations differently.

### Overview

An approach to automated additive concentration optimization during a hydraulic fracturing operation is described. Whereas traditional approaches may use physics-based or empirical models or rule of thumb or historical lookup, the described approach utilizes real-time calibration and model building to generate a real-time model during a well treatment operation for predicting surface pressure as a function of additive (e.g., friction reducer) concentration. Predicted surface treatment (also referred to as treating) pressures may be used to optimize the additive concentration for any performance objective function. While traditional approaches may achieve less than optimal performance improvements via iterative adjustments, the described approach may achieve optimal performance or changes during the well treatment. An optimal adjustment may be a change that maintains an operational parameter at a value that either maximizes or minimizes a related objective function. For example, an optimal additive concentration may be an additive concentration that minimizes an objective function related to operational costs. However, other operational variables and relationships may be considered.

Some implementations may include machine-implemented methodologies for optimizing the additive concentrations. Such a machine-implemented methodology may include operations and components for developing a mathematical model for surface treating pressure as a function of additive (e.g., friction reducer) concentration by systematically changing the additive concentration during a first fracturing stage/treatment—this may be known as the calibration stage. Differentiating this mathematical equation representing the mathematical model may indicate changes in surface treating pressure for a change in additive concentration for a given/initial conditions at any time. Since water quality remains unchanged for a given well, the mathematical model may facilitate simple yet effective control of wellbore friction and/or perforation fiction and/or tortuosity friction or any combination thereof. The additive concentration may further be optimized by accounting various cost/loss/error functions related to surface treating pressure and additive concentration (e.g., HHP, time, equipment performance, maintenance, reliability, fuel consumption, carbon emissions, and/or other operations performance measures). The machine-implemented methodology for optimizing the additive concentration may be indirectly lumped in water quality parameters, proppant concentration, chemical type, etc., but still enables determination of the optimum additive concentration with reliable accuracy. The machine-implemented methodology may also be evolutionary, allowing for re-calibration as more fracturing stages are completed towards the heel of the well.

The description that follows includes example systems, methods, techniques, and program flows that embody aspects of the disclosure. However, it is understood that this disclosure may be practiced without these specific details. For instance, this disclosure refers to additive concentration optimization in real-time for wellbore treatment operations, hydraulic fracturing operations or injection operations in hydrocarbon formations. Aspects of this disclosure may also be applied to any other configuration of devices configured to perform the described operations. For clarity, some well-known instruction instances, protocols, structures, and techniques have been omitted.

### Example Hydraulic Fracturing System

FIG. 1 is a block diagram illustrating a fracturing spread configured for hydraulically fracturing subsurface formations in one or more wells, according to some implementations. The fracturing spread described herein may be part of a larger system for drilling and fracturing well. The fracturing spread 100 may include a wellhead 102 that is connected to a wellbore. The wellbore (not shown) may be fluidically connected to one or more subsurface formations for the purpose of hydrocarbon recovery. Although FIG. 1 shows only one wellhead 102, there may be any suitable number of wellheads 102 and wells.

The wellhead 102 may be connected to a manifold 104 via piping 106. The piping 106 may include one or more pipes between the wellhead 102 and the manifold 104. The manifold 104 may include a plurality of valves 108 and various internal piping (not shown) for performing hydraulic fracturing operations.

The manifold 104 may be connected to one or more fracturing pumps (“frac pumps”) 112. The manifold 104 also may be connected to a blender 116 via piping 118. The blender 116 may be connected via piping 128 to one or more chemical containers 120, water containers 122, and acid containers 124. The blender 116 also may be connected to a sand conveyor 130, where the sand conveyor 130 may be connected to the container of fracturing sanders 132. In some implementations, the one or more chemical containers 120 may contain additives such as friction reducers.

The fracturing spread 100 may also include a power unit 101 configured to provide power to the frac pumps 112. In some implementations, one or more of the frac pumps may be electric frac pumps, and each of the electric frac pumps may be powered by the power unit 101. If there are multiple electric frac pumps in the fracturing spread 100, there may be one power unit 101 that may supply power to the electric frac pumps, each electric frac pump within the fracturing spread 100 may have a dedicated power unit 101, there may be multiple power units 101 that supply power to respective subsets of electric frac pumps, etc. In some implementations, the power unit 101 may provide power to other components in the fracturing spread 100 such as the blender 116, sand conveyor 13, etc. The power unit 101 may include any suitable components that may supply power for the fracturing spread such as one or more generators (such as a natural gas generator, a diesel generator, a combination of the like, etc.), an electric grid, etc. and/or a combination of power sources.

The fracturing spread 100 also may include a control system 134 configured to control one or more of the components of the fracturing spread 100. In some implementations, the control system 134 directly controls the equipment. However, the control system 134 may interact with various equipment controllers (not shown) and sensors to perform operations of the fracturing spread 100. For example, the fracturing spread 100 may include separate controllers (not shown) for the frac pumps 112, manifold 104, blender 116, and wellhead 102. The control system 134 may transmit commands to these separate controllers to change configurations (such as valve position, flow rate, chemical concentration, etc.) of the frac pumps 112, manifold 104, blender 116, chemical containers 120, etc. wellhead 102.

In some implementations, the control system 134 may be a computer. The control system 134 may include an optimizer 136. The control system 134 may be configured to send commands to components of the fracturing spread 100 (such as the frac pumps 112, a valve controller, etc. to execute the commands by implementing the suggested fracturing parameters into the hydraulic fracturing operation. The optimizer 136 may be configured to determine a relationship between an additive concentration (e.g., a chemical in the chemical containers 120) and surface treating pressure. The optimizer 136 may generate a real-time model for treating pressure predictions based on additive concentration. The relationship between treating pressure and additive concentration may be used to determine an optimal additive concentration with respect to either a maximum or minimum of an objective function (i.e., an additive concentration that minimizes a cost objective function). The control system 134 may then actuate changes within the fracturing spread 100 to achieve the optimum additive concentration.

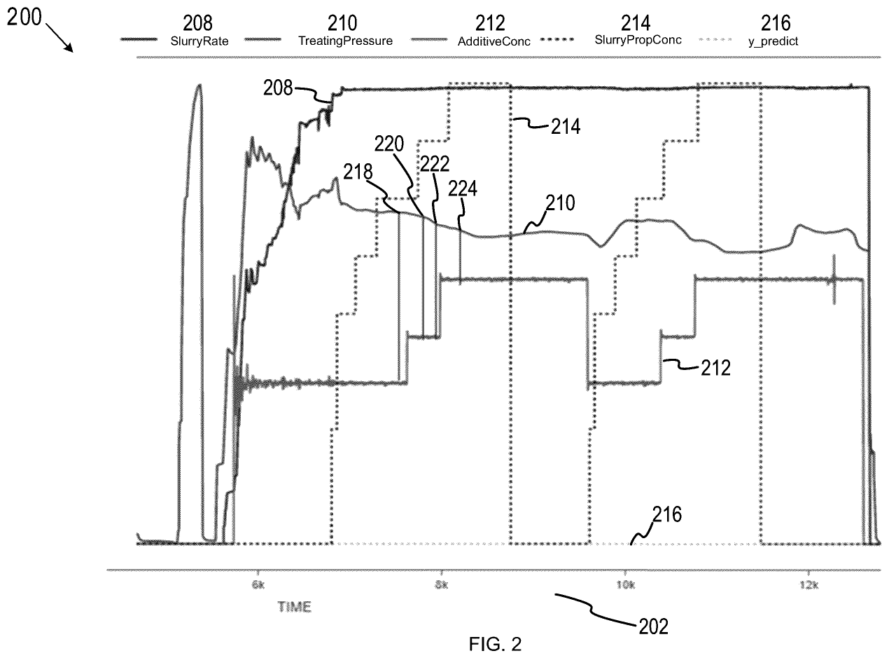

FIG. 2 is an illustration of an example treatment execution 200, according to some implementations. The treatment execution 200 includes an X-axis of time in seconds. The treatment execution 200 further includes trends that are prone change with time throughout a hydraulic fracturing operation such as a slurry rate 208, a treating pressure 210, an additive concentration 212, a proppant concentration 214 of the slurry, and a predicted treatment pressure 216. During a calibration stage of the optimizer 136 (as depicted), the trend of predicted treatment pressure 216 may not yet be active. In some implementations, the additive concentration 212 may refer to a concentration of friction reducer pumped into the well, although other additive concentrations may be considered.

The optimizer 136 may be configured to alter the additive concentration 212 systematically for a minimum of two set points during a calibration stage. In some implementations, other variables may also be adjusted. After each change or set point, a response in the treating pressure 210 is recorded once an interval of time (e.g., five minutes) has elapsed. For example, a first pressure (P1) set point 218 may be taken at a first additive concentration. A second pressure (P2) set point 220 may be taken at a higher additive concentration after one wellbore volume of fluid is pumped. A next P1 pressure 222 is collected just before changing to a next set point of additive concentration. A next P2 pressure 224 may also be recorded at a higher additive concentration after one wellbore volume of fluid is pumped. Although two set points are shown, multiple changes in treating pressure vs. additive concentration change may be observed. From the treating pressures 218-224, a semi-empirical relationship between the additive concentration 212 and treating pressure 210 may be determined. Alternatively, changes in treating pressure may be recorded by decreasing the additive concentration in steps or gradual changes. For example, a first pressure (P1) set point 218 may be taken at a first additive concentration. A second pressure (P2) set point 220 may be taken at a lower additive concentration (not shown) after one wellbore volume of fluid is pumped. A next P1 pressure 222 may be collected just before changing to a next set point of additive concentration, as is a next P2 pressure 224 may be taken at a lower additive concentration after one wellbore volume of fluid is pumped. Although two set points are shown, multiple changes in treating pressure vs. additive concentration change may be observed. Systematic changing of the additive concentration and observing changes in the treatment pressure may be used to determine a relationship between treating pressure and additive concentration. For example, from the treating pressures 218-224, a semi-empirical relationship between the additive concentration 212 and treating pressure 210 may be determined.

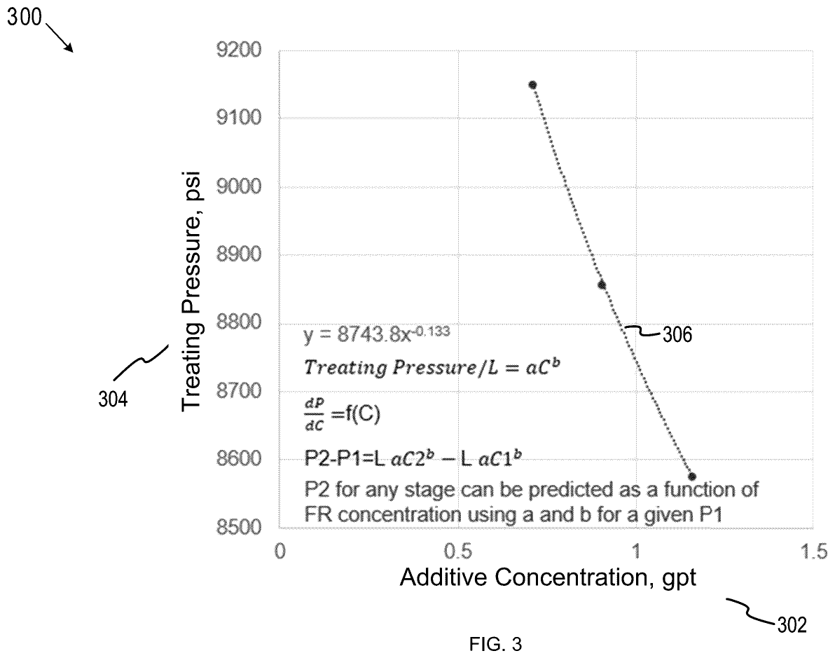

In some implementations, the optimizer 136 may determine the relationship between treating pressure and additive concentration during a hydraulic fracturing or any injection operation. This relationship may be used to build a model. FIG. 3 is a plot 300 depicting a relationship between the additive concentration and treating pressure, according to some implementations. The plot 300 includes an X-axis 302 of additive concentration in units of gallons per thousand gallons (gpt). The plot 300 also includes a Y-axis 304 of treating pressure (taken at the surface) in pounds per square inch (psi).

From a calibration stage similar to that portrayed in FIG. 2, the optimizer 136 may plot recorded treating pressures and corresponding additive concentrations with the addition of fitting constants, as shown in Equation 1:

$$\frac{TreatingPressure}{L} = {aC}^{b} \qquad ( Eq . 1 )$$

where TreatingPressure is the treating pressure output by the frac pumps 112, L is the treatment stage length from surface, a is a first fitting parameter, b is a second fitting parameter, and C is the concentration of the additive. In some implementations, Equation 1 may be rewritten to account for hydrostatic pressure, where TreatingPressure/L is instead replaced by (TreatingPressure+HydrostaticPressure)/L. In some implementations, the relationship between treating pressure and additive concentration may be represented by a power law equation, although other functions may be used.

The differential of Equation 1 grants a relationship between treating pressure and additive concentration that may be applied to same stage/treatment at different time interval or any other stages/treatments outside of the calibration stage. The differential of Equation 1 is shown in Equation 2:

$$\frac{dP}{dC} = f ( C ) \qquad ( Eq . 2 )$$

where dP is a change in treating pressure, dC is a change in additive concentration, and f(C) is a trend of treating pressure as a function of additive concentration, represented by the curve 306.

Integrating Equation 2 with respect to a first and second treating pressure results in Equation 3:

$$P 2 - P 1 = LaC {2}^{b} - LaC {1}^{b} \qquad ( Eq . 3 )$$

where P2 is a predicted final treating pressure, P1 is a known treating pressure, L is fracture stage length, a is a first fitting parameter, b is a second fitting parameter, C2 is a second concentration of the additive, and C1 is a first known concentration of the additive. Using Equation 3, a real-time model used by the optimizer 136 may be used to predict a treating pressure P2 as a function of additive concentration, a, and b for any given P1. P1 may be measured at C1, and P1, C1 may be known. Thus, a treating pressure (P2) may be predicted from a given change in additive concentration from C1 to C2. In some implementations, a and b may be fitting constants depending on slurry rate, proppant concentration, additive (e.g., friction reducer) stability, water quality, wellbore completions i.e. number of perforations, number of perforations clusters, etc. However, in other implementations, a and b may also fluctuate.

A predicted value of P2 may be used to estimate a new hydraulic horsepower output by the frac pumps 112 for a new additive concentration C2. Equation 3 and this relation to HHP may be used to estimate an optimized additive concentration based on an optimal objective function value or optimum treating pressure as an example, the optimal treating pressure determined based on HHP, or other performance measures. For example, reducing the HHP for fracturing an entire well (or multiple wells on a pad) within reasonable limits may lower fuel consumption or maintenance by the frac pumps 112, thus lowering operational expenditures.

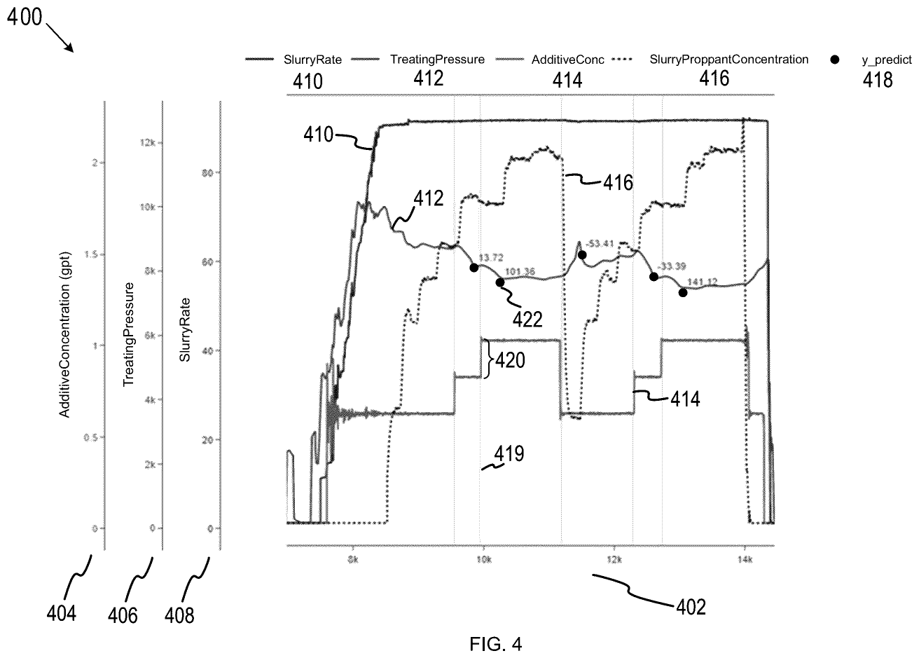

FIG. 4 is an illustration depicting an example treatment execution 400 including predicted treating pressures, according to some implementations. The treatment execution 400 includes an X-axis 402 of time in seconds and various Y-axes including a Y-axis 404 of additive concentration in gpt, a Y-axis 406 of treating pressure in psi, and a Y-axis 408 of slurry rate in barrels per minute (bpm). The treatment execution 400 also includes a slurry rate 410, treating pressure 412, an additive concentration 414, a proppant concentration 416 in the slurry, and predicted treating pressures 418. The predicted treating pressures 418 may be predicted by the optimizer 136. The optimizer 136 may use a model based on Equation 3 to make predictions of treating pressures. For example, at a concentration alteration time 419, the additive may be increased from a first concentration, C1, to a second concentration, C2. For example, based on a known treating pressure at C1, a predicted surface treating pressure 422 may be estimated based on the concentration change 420. In some implementations, the predicted treating pressures 418 may be predicted in real-time.

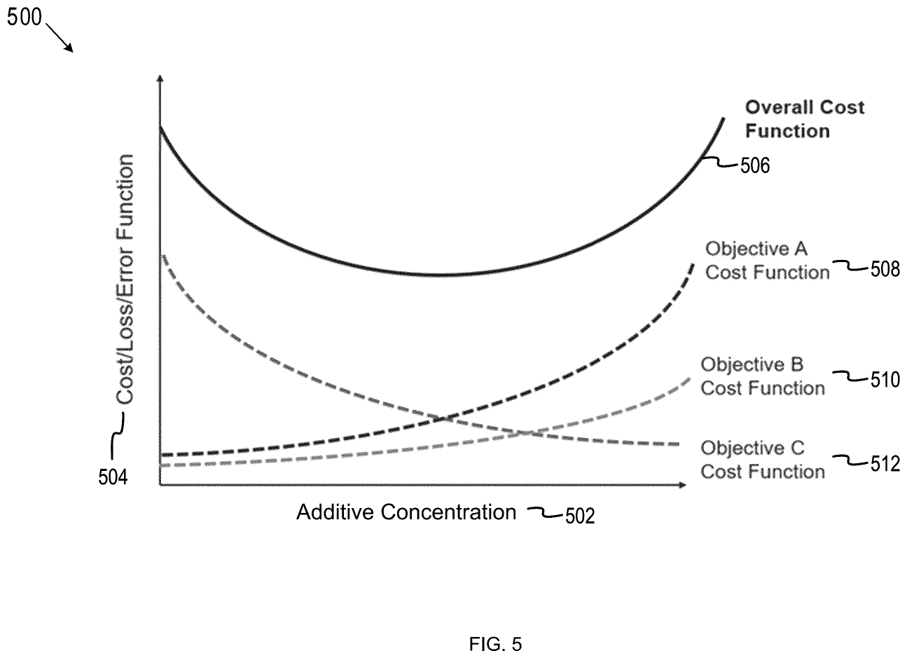

Determining an optimized additive concentration may depend upon the context of what it means to be “optimized”. For example, the additive concentration may be optimized with respect to cost—i.e., an optimized additive concentration is the concentration that incurs the least operational costs. For example, because operational costs are also linked to treating pressure, and treating pressure correlates to HHP and fuel consumption of the frac pumps 112, an optimal additive concentration may be one that lowers the HHP of the frac pumps 112 by maintaining a satisfactory overall frictional resistance. The additive concentration may be further optimized by accounting various other cost/loss/error functions (e.g., HHP, time, equipment performance, maintenance, carbon emissions, reliability, and/or the other operations performance measures as shown in FIG. 5.

FIG. 5 is a plot 500 depicting a plurality of objective functions, according to some implementations. The plot 500 includes an X-axis 502 of additive (e.g., friction reducer, treatment chemicals, etc.) concentration and a Y-axis 504 of an operation performance measure. In some implementations, the X-axis 502 may measure treating pressure in psi. Plot 500 includes example functions related to cost, although other operations performance measures may be used. An overall cost function 506 may represent total costs for a hydraulic fracturing operation and may be based upon a plurality of individual objective cost functions 508-512. For example, a first objective cost function 508 may relate to purchasing costs of the additive, a second objective cost function 510 may relate to repair costs on equipment based on run-time, and a third objective cost function 512 may relate to fuel costs of the frac pumps 112—however, other parameters and objectives may be considered. The objective functions may relate to any parameter and are not limited to cost. For example, the objective functions may be configured with respect to time-based criteria. In some implementations, the optimal additive concentration may be the concentration that minimizes the overall cost function 506. In some implementations, the overall cost function 506 may include a function related to treating pressure. For example, other objective functions similar to the objective functions 508-512 may also be related to treating pressure.

### Example Flowchart of Operations

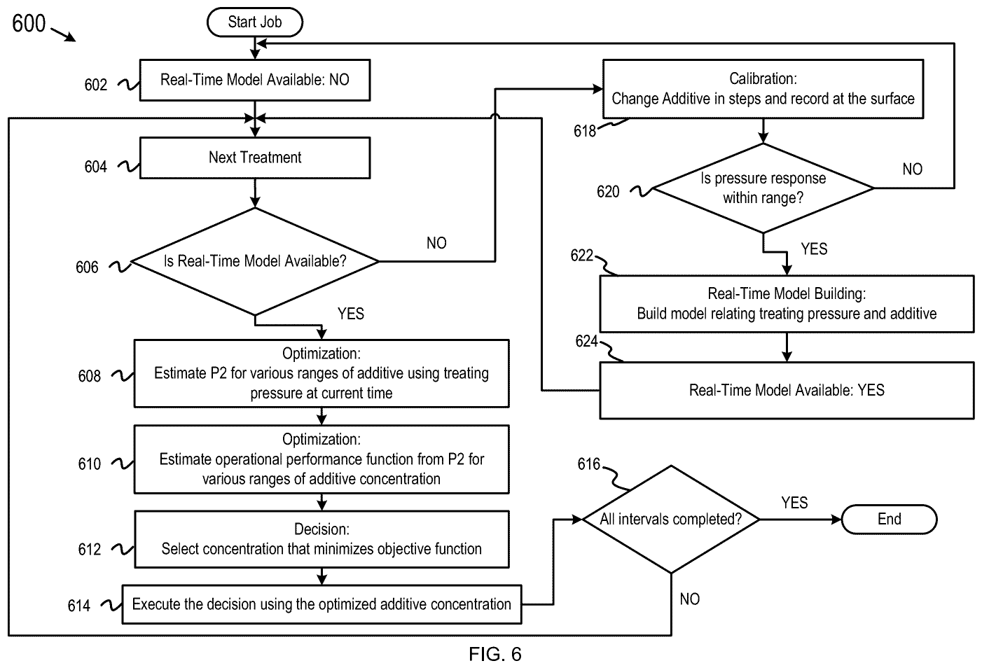

A flowchart of example operations for pump trajectory optimization is now described. FIG. 6 is a flowchart 600 depicting example operations for real-time model building and additive concentration optimization, according to some implementations. The flowchart 600 may describe operations with reference to FIGS. 1-5. Flow of the flowchart 600 begins at block 602.

At block 602, a determination is made that a real-time model for optimizing the hydraulic fracturing operation is not available. For example, there may not be a computerized model available that is configured to optimize an additive concentration to achieve a specific objective (reducing HHP, lowering costs, etc.). Thus, a computerized real-time model may need to be generated. In some implementations, the real-time model may be generated on-site in the control system 134. Flow progresses to block 604.

At block 604, the next well treatment begins. Flow progresses to block 606.

At block 606, the flow of the flowchart 600 splits into two workflows. Assuming a computerized real-time model is available via the control system 134, flow progresses to block 608. If a computerized real-time model needs to be created (i.e., one is not available), then flow progresses to block 618.

At block 608, a plurality of treating pressures, P2, are estimated for various ranges of additive concentrations at current times. For example, P2 may be estimated based on C1, C2, and P1 at the current time by the optimizer 136 of the control system 134. The optimize 136 may include a real-time model configured to make treating pressure predictions based on Eq. 3. The real-time model may also factor in one or more cost functions. Flow progresses to block 610.

At block 610, the optimizer 136 may estimate an operational performance function from the predicted treating pressure (P2) for various ranges of additive concentration. For example, the optimizer may estimate an operational performance function similar to the overall cost function 506, one of the other objective functions 508-512, etc. The operational performance function (also referred to as the objective function) may have a relationship with treating pressure, and the treating pressure is related to the additive concentration. Flow progresses to block 612.

At block 612, the optimizer 136 selects an additive concentration that minimizes the objective function. For example, the optimizer 136 may select an additive concentration that, for a predicted treating pressure, minimizes the overall cost function 506. Previously, the model of the optimizer 136 was used to predict P2 based on additive concentrations C1 and C2. However, for real-time optimization once deployed, the optimizer 136 must consider both the relationship between additive concentration and treating pressure (Eq. 3) and a relationship between treating pressure and the objective function—in the example, the objective is to lower costs. In some implementations, the two relationships may be considered simultaneously to determine an optimal additive concentration that optimizes an overall objective function such as the overall cost function 506 with respect to treating pressure.

Traditional approaches may use downhole gauges to measure wellbore friction, but this does not encapsulate all sources of cost accumulation. The costs of the frac pumps 112 are largely governed by treatment pressure and not solely on the friction registered by the downhole gauge. Thus, establishing the relationship between the treating pressure and the objective function may better encompass the total costs at the frac pumps 112 than would a relationship between solely an overall friction and the objective function.

Ultimately, because the objective (costs) is linked to treating pressure and/or HHP, P2 must be optimized. In some implementations, an optimized treating pressure may be predicted that achieves the lowest costs (reduced HHP). The predicted optimized treating pressure may be used to determine an optimal additive concentration. Thus, the optimizer 136 may predict one or more treating pressures that optimizes the overall cost function 506, and the optimized treating pressure prediction leads to an optimized additive concentration calculation that optimizes (i.e., minimizes) the overall cost function 506. In another example, one or more parts of an overall cost function may directly depend only additive concentration whereas other part(s) of the overall cost function may depend on treating pressure and thereby again indirectly depends on additive concentration through the established relationship by the optimizer 136 between treating pressure and additive concentration. Thus, the optimizer 136 may predict one or more values, sets, etc. of optimized additive concentration and treating pressures that optimizes the overall cost function 506. The optimizer 136 may also consider other cost functions contributing to the overall cost function 506 that do not relate to the treating pressure. For example, the first objective cost function 508 may relate to additive costs. While this may not relate to treating pressure, the example cost function would directly depend upon additive concentration and contributes to overall objective function.

In one example, the optimizer 136 may estimate, based on the overall cost function 506, that the frac pumps 112 consume the least amount of fuel while pumping at 6,000 psi, given the constraints of a current job. Thus, 6,000 psi is the predicted optimal treating pressure—in Eq. 3, this becomes P2. There may exist an additive concentration that achieves this optimal treating pressure while also maintaining the minimum of the overall cost function 506. In some implementations, the additive concentration achieves the optimal treating pressure via overall friction management. The optimizer 136 may calculate the optimized additive concentration using Eq. 3, where C2 is unknown and P2 is the predicted optimal treating pressure. Flow progresses to block 614.

At block 614, the optimizer 136 may execute a decision using the optimized additive concentration of block 612. The optimizer 136 may be configured to actuate various equipment such as the one or more chemical containers 120 and frac pumps 112 via the control system 134 to implement the optimized additive concentration of block 612. Flow progresses to block 616. The blocks 608 to 614 may be repeated at various time intervals within a single treatments allowing evolutionary optimization and decisions execution.

At block 616, a decision is made regarding whether all intervals of a job are complete. The process described in blocks 604-614 may be repeated on all stages of the well and pad to achieve the best operational performance. If all intervals are complete, flow of the flowchart 600 ceases. If all intervals have not been completed, flow returns to block 604 where a subsequent treating begins. Assuming no model is available for the next treatment, flow progresses to block 618.

At block 618, the optimizer 136 may perform calibration steps to form a relationship between treating pressure and additive concentration. This may be similar to the calibration stage of FIG. 2. Changes in additive concentration may induce changes in treating pressure that are recorded. Flow progresses to block 620.

At block 620, the optimizer 136 may determine whether the pressure responses are within a satisfactory range. If yes, flow progresses to block 622 where a relationship between additive concentration treating pressure is determined. If the treating pressure response is outside the desired range, flow returns to block 602. Assuming the pressure response is within a satisfactory range, flow progresses to block 622.

At block 622, the optimizer 136 may build a model in real-time relating treating pressure and additive concentration based on the calibration steps. For example, the optimizer 136 may use Equations 1-3 to build a relationship between treating pressure and additive concentration in real-time that will be used to reduce the HHP or optimize any operational parameter for the entire well within accuracy limits. In some implementations, the model may also be configured to factor in other parameters impacted by additive concentration and treating pressure. Flow progresses to block 624. Alternatively, flow may optionally progress from block 622 to block 606 (not shown) to continue on optimization steps as the model is now available.

At block 624, the real-time model may be available and pending deployment. Real-time models such as those created by the optimizer 136 may enable increased automation and achieve higher surface efficiencies, lower costs per barrel of oil equivalent (BOE) produced, and reductions in stage transition time. Flow of the flowchart 600 ceases.

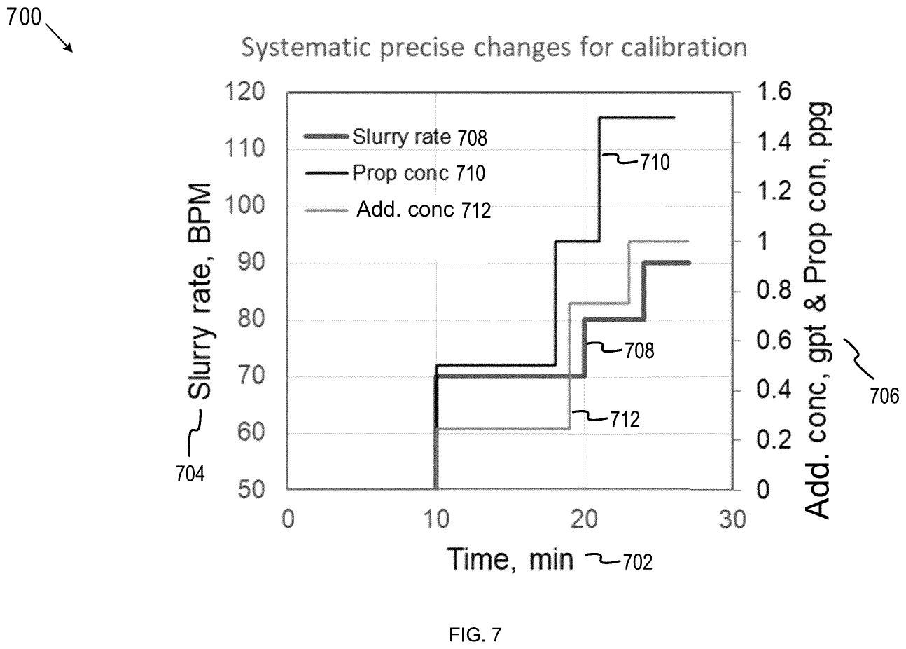

In some implementations, the real-time model may be extended to account for changes in slurry rate and proppant concentration or water quality (TDS i.e. Total Dissolved Solids, any specific ion concentration in water, etc.) during the calibration stage. FIG. 7 is a plot 700 depicting calibration adjustments that factor in slurry rate and proppant concentration, according to some implementations. While the calibration adjustments in the plot 700 factor in slurry rate and proppant concentration, other variables may also be considered. The plot 700 includes an X-axis 702 of time in minutes, a first Y-axis 704 of slurry rate in bpm, and a second Y-axis 706 of both an additive concentration in gpt and a proppant concentration in ppg. The optimizer 136 may perform systematic precise changes to the slurry rate 708, proppant concentration 710, additive concentration 712, etc. in the initial stage of the hydraulic fracturing operation. In some implementations, the optimizer 136 may perform systematic precise changes to any number of other variables in the initial stage. The optimizer 136 may record pressure responses in the treating pressure to each of the changes.

Using the above strategy, the optimizer 136 may develop an equation for predicting P2 for a given change in slurry rate, proppant concentration, and additive concentration:

$$\frac{d ( \frac{P}{L} )}{dC} = f ( {C}_{A ,} {C}_{P ,} {Q}_{S} ) \qquad ( Eq . 4 )$$

where d (P/L) is a change in treating pressure over the length of the stage, dC is a change in concentration, and f (C_{A}, C_{P}, Q_{S}) is a trend of treating pressure as a function of additive concentration (C_{A}), proppant concentration (C_{P}), and slurry rate (Q_{S}).

### Example Computer

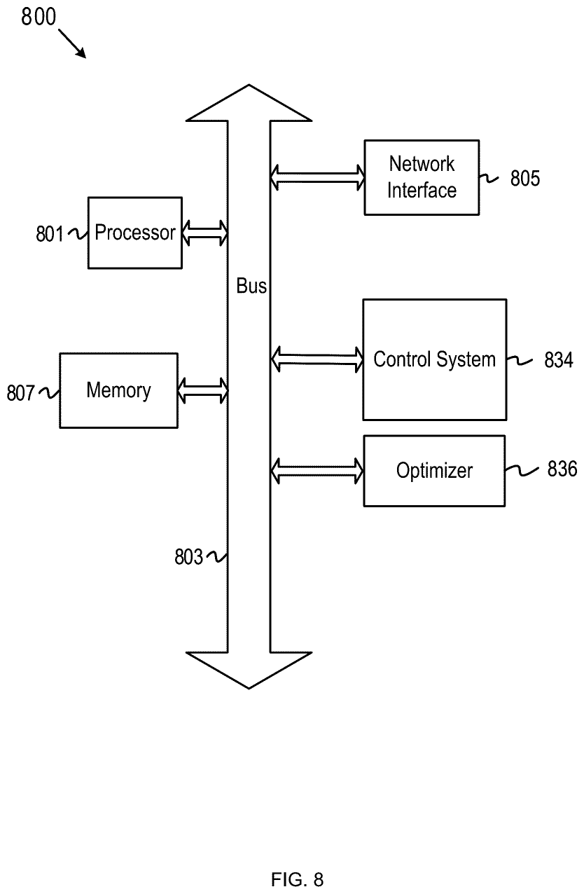

FIG. 8 is a block diagram depicting an example computer 800, according to some implementations. The computer 800 includes a processor 801 (possibly including multiple processors, multiple cores, multiple nodes, and/or implementing multi-threading, etc.). The computer 800 includes memory 807. The memory 807 may be system memory or any one or more of the above already described possible realizations of machine-readable media. The computer 800 also includes a bus 803 and a network interface 805. The computer 800 may communicate via transmissions to and/or from remote devices via the network interface 805 in accordance with a network protocol corresponding to the type of network interface, whether wired or wireless and depending upon the carrying medium. In addition, a communication or transmission may involve other layers of a communication protocol and or communication protocol suites (e.g., transmission control protocol, Internet Protocol, user datagram protocol, virtual private network protocols, etc.).

The computer 800 also includes a control system 834 and optimizer 836 which may perform the operations described herein. For example, the control system 834 may be configured to actuate the equipment depicted in FIG. 1 similar to the control system 134. The control system 834 may also be configured to perform the operations of at least block 614. The optimizer 836 may be configured to perform the above-described operations with reference to the optimizer 136. The control system 834 and the optimizer 836 may be in communication. Any one of the previously described functionalities may be partially (or entirely) implemented in hardware and/or on the processor 801. For example, the functionality may be implemented with an application specific integrated circuit, in logic implemented in the processor 801, in a co-processor on a peripheral device or card, etc. Further, realizations may include fewer or additional components not illustrated in FIG. 8 (e.g., video cards, audio cards, additional network interfaces, peripheral devices, etc.). The processor 801 and the network interface 805 are coupled to the bus 803. Although illustrated as being coupled to the bus 803, the memory 807 may be coupled to the processor 801.

### Example Method

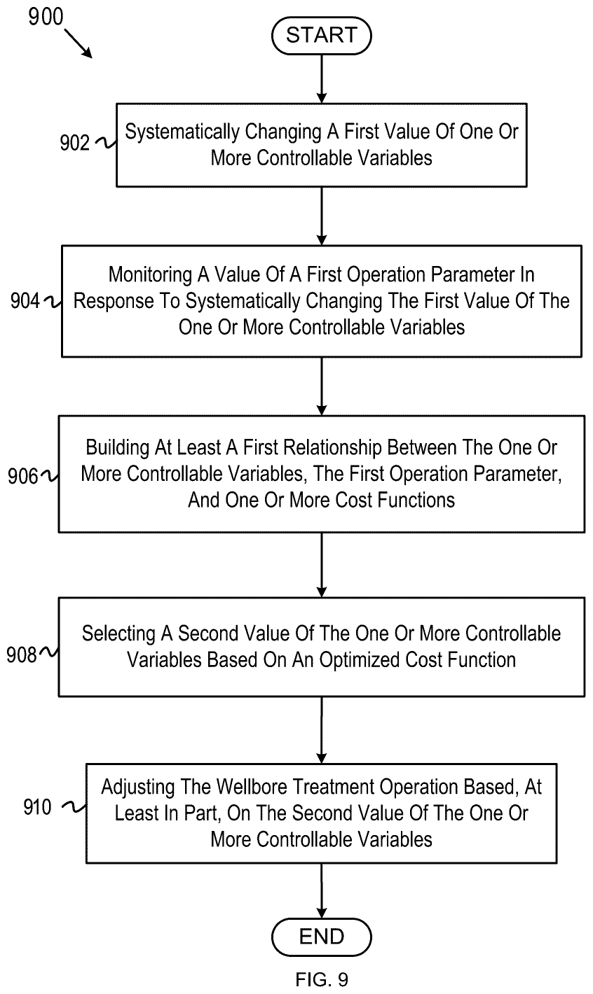

FIG. 9 is a flowchart of an example method 900 for optimizing one or more controllable variables for use in a wellbore treatment operation, according to some implementations. The flowchart includes operations which may be described with reference to FIGS. 1-8. Operations of the method 900 begin at block 902.

At block 902, the method includes systematically changing a first value of the one or more controllable variables, according to some implementations. For example, the one or more controllable variables may include a material concentration such as an additive concentration, although any other controllable variable or combinations thereof may be used. An additive concentration at the first pressure (P1) set point 218 may be changed to an increased additive concentration at the second pressure (P2) set point 220. However, any other suitable controllable variable may be systematically changed. Flow progresses to block 904.

At block 904, the method includes monitoring a value of a first operation parameter in response to systematically changing the first value of the one or more controllable variables. For example, the first operation parameter may include the treating pressure 210 of the frac pumps 112, although other properties may be used. The next P1 pressure 222 and next P2 pressure 224 may be observed while monitoring treating pressure in response to changes in the additive concentration.

With reference to FIG. 2, the optimizer 136 may be configured to alter the additive concentration 212 systematically for a minimum of two set points during a calibration stage. In some implementations, other variables may also be adjusted. After each change or set point, a response in the treating pressure 210 is recorded once an interval of time (e.g., five minutes) has elapsed. For example, a first pressure (P1) set point 218 may be taken at a first additive concentration. A second pressure (P2) set point 220 may be taken at a higher or lower additive concentration after one wellbore volume of fluid is pumped. A next P1 pressure 222 is collected just before changing to a next set point of additive concentration. A next P2 pressure 224 may be taken at a higher or lower additive concentration after one wellbore volume of fluid is pumped. Although two set points are shown, multiple changes in treating pressure vs. additive concentration change may be observed. Flow progresses to block 906.

At block 906, the method includes building at least a first relationship between the one or more controllable variables, the first operation parameter, and one or more cost functions. For example, the systematic changing of the additive concentration and observing changes in the treatment pressure may be used to determine a relationship between treating pressure and additive concentration. In one example, the treating pressures 218-224 may be used to determine a semi-empirical relationship between the additive concentration 212 and treating pressure 210.

With reference to FIG. 6, the optimizer 136 may also relate the additive concentration 212 and treating pressure 210 to one or most cost functions. For example, the optimizer 136 may estimate a cost function from the predicted treating pressure (P2) for various ranges of additive concentration. In some implementations, this cost function may be similar to the overall cost function 506. The cost function may have a relationship with treating pressure, and the treating pressure is related to the additive concentration. Flow progresses to block 908.

At block 908, the method includes selecting a second value of the one or more controllable variables based on an optimized cost function. For example, the optimizer 136 may be configured to select an additive concentration based on an optimized overall objective function. For example, the optimizer 136 may determine an optimized additive concentration and optimized treating pressure that minimizes the cost function of block 906. The selected additive concentration may, for example, be a concentration of a friction reducer that reduces the HHP of the frac pumps 112 within acceptable limits, contributing to reduced fuel costs. In some implementations, part of the cost function, which may be similar to the overall cost function 506, may directly depend on additive concentration, whereas another part or parts of the cost function may depend on treating pressure. Because the optimizer 136 has established a relationship between additive concentration and treating pressure, the treating pressure and additive concentration that optimizes the cost function of block 906 may be selected. When lowering costs is the objective, the optimal additive (or any other material) concentration and the optimal treating pressure may minimize the cost function of block 906. However, this may change for other controllable variables and objective functions (other than cost).

Previously, the model of the optimizer 136 was used to predict P2 based on additive concentrations C1 and C2. However, for real-time optimization once deployed, the optimizer 136 must consider both the relationship between additive concentration and pressure (Eq. 3) and a relationship between treating pressure and the objective function—in the example, the objective is to lower costs. Optimizing the cost function may then be followed by optimization of the additive concentration in real-time. Flow progresses to block 910.

At block 910, the method includes adjusting the wellbore treatment operation based, at least in part, on the second value of the one or more controllable variables. For example, the optimizer 136 may communicate the optimal additive concentration of block 908 to the control system 134, although other controllable variables may be used. The control system 134 may actuate various components within the fracturing spread 100 (various valves, the frac pumps 112, the chemical containers 120, etc.) to achieve the selected additive concentration in real-time. The optimal additive concentration may, for example, lower a hydraulic horsepower of one or more of the frac pumps 112 or lowers overall cost or expenditure of fracturing treatment. Flow of the method 900 ceases.

Any of the relationships described herein (such as the relationship between treating pressure and operational costs, relationship between additive concentration and treating pressure, etc.) may be referred to with any suitable distinguishing identifier such as first relationship, second relationship, third relationship, fourth relationship, etc. Any combination or permutation of the relationships described herein may be used to determine and/or optimize one or more controllable variables in the wellbore treatment operation.

While the aspects of the disclosure are described with reference to various implementations and exploitations, it will be understood that these aspects are illustrative and that the scope of the claims is not limited to them. In general, techniques for real-time calibration and model generation for additive concentration optimization as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

### EXAMPLE IMPLEMENTATIONS

Implementation #1: A method comprising: systematically changing a first value of one or more controllable variables used in a wellbore treatment operation; monitoring a value of a first operation parameter in response to systematically changing the first value of the one or more controllable variables; building at least a first relationship between the one or more controllable variables, the first operation parameter, and one or more cost functions; selecting a second value of the one or more controllable variables based on an optimized cost function; and adjusting the wellbore treatment operation based, at least in part, on the second value of the one or more controllable variables.

Implementation #2: The method of Implementation 1, wherein systematically changing the first value of the one or more controllable variables comprises: altering, during the wellbore treatment operation, a material concentration at a plurality of set points.

Implementation #3: The method of any one or more of Implementations 1 or 2, wherein monitoring the value of the first operation parameter in response to systematically changing the value of the one or more controllable variables comprises: monitoring, during the wellbore treatment operation, changes in the first operation parameter over the plurality of set points.

Implementation #4: The method of any one or more of Implementations 1-3, further comprising: determining a second relationship between change in one or more controllable variables and change in the first operation parameter across the plurality of set points; integrating the second relationship; and determining, based on the integrating, a third relationship between the first operation parameter and the one or more controllable variables.

Implementation #5: The method of any one or more of Implementations 1-4, further comprising: determining a fourth relationship between the one or more controllable variables and an objective function, wherein the one or more controllable variables are related to the first operation parameter via the third relationship; predicting, based on the third and fourth relationships, an optimal first operation parameter that optimizes the objective function; and determining an optimized controllable variable based on the optimal first operation parameter.

Implementation #6: The method of any one or more of Implementations 1-5, further comprising: generating a real-time model based, at least in part, on the third and fourth relationships; and deploying the real-time model during the wellbore treatment operation.

Implementation #7: The method of any one or more of Implementations 1-6, wherein adjusting the wellbore treatment operation comprises: performing at least part of the wellbore treatment operation with the optimized controllable variable, wherein the first operation parameter is a treatment pressure of one or more pumps, and wherein the one or more controllable variables includes an additive concentration.

Implementation #8: A system comprising: one or more pumps proximate to the wellbore; a processor; and a computer-readable medium having instructions executable by the processor, the instructions including: instructions to systematically change a first value of one or more controllable variables to be used in a wellbore treatment operation of a wellbore formed in one or more subsurface formations; instructions to monitor a value of a first operation parameter in response to systematically changing the first value of the one or more controllable variables; instructions to build at least a first relationship between the one or more controllable variables, the first operation parameter, and one or more cost functions; instructions to select a second value of the one or more controllable variables based on an optimized cost function; and instructions to adjust the wellbore treatment operation based, at least in part, on the second value of the one or more controllable variables.

Implementation #9: The system of Implementation 8, further comprising: one or more containers including one or more materials, wherein the instructions to systematically change the first value of the one or more controllable variables comprise instructions to alter, during the wellbore treatment operation, a material concentration of the one or more materials at a plurality of set points.

Implementation #10: The system of any one or more of Implementations 8 or 9, wherein the instructions to monitor the value of the first operation parameter in response to the systematic change of the value of the one or more controllable variables comprise: instructions to monitor, during the wellbore treatment operation, changes in the first operation parameter over the plurality of set points.

Implementation #11: The system of any one or more of Implementations 8-10, further comprising: instructions to determine a second relationship between change in one or more controllable variables and change in the first operation parameter across the plurality of set points; instructions to integrate the second relationship; and instructions to determine, based on the integration, a third relationship between the first operation parameter and the one or more controllable variables.

Implementation #12: The system of any one or more of Implementations 8-11, further comprising: instructions to determine a fourth relationship between the one or more controllable variables and an objective function, wherein the one or more controllable variables are related to the first operation parameter via the third relationship; instructions to predict, based on the third and fourth relationships, an optimal first operation parameter that optimizes the objective function; and instructions to determine an optimized controllable variable based on the optimal first operation parameter.

Implementation #13: The system of any one or more of Implementations 8-12, wherein the instructions to adjust the wellbore treatment operation comprise: instructions to perform at least part of the wellbore treatment operation with the optimized controllable variable, and wherein the first operation parameter is a treatment pressure of the one or more pumps.

Implementation #14: One or more non-transitory machine-readable media including instructions executable by a processor, the instructions comprising: instructions to systematically change a first value of one or more controllable variables to be used in a wellbore treatment operation of a wellbore formed in one or more subsurface formations; instructions to monitor a value of a first operation parameter in response to systematically changing the first value of the one or more controllable variables; instructions to build at least a first relationship between the one or more controllable variables, the first operation parameter, and one or more cost functions; instructions to select a second value of the one or more controllable variables based on an optimized cost function; and instructions to adjust the wellbore treatment operation based, at least in part, on the second value of the one or more controllable variables.

Implementation #15: The machine-readable media of Implementation 14, wherein the instructions to systematically change the first value of the one or more controllable variables comprise: instructions to alter, during the wellbore treatment operation, a material concentration at a plurality of set points.

Implementation #16: The machine-readable media of any one or more of Implementations 14 or 15, wherein the instructions to monitor the value of the first operation parameter in response to the systematic change of the value of the one or more controllable variables comprise: instructions to monitor, during the wellbore treatment operation, changes in the first operation parameter over the plurality of set points.

Implementation #17: The machine-readable media of any one or more of Implementations 14-16, further comprising: instructions to determine a second relationship between change in one or more controllable variables and change in the first operation parameter across the plurality of set points; instructions to integrate the second relationship; and instructions to determine, based on the integration, a third relationship between the first operation parameter and the one or more controllable variables.

Implementation #18: The machine-readable media of any one or more of Implementations 14-17, further comprising: instructions to generate a real-time model based, at least in part, on the third and fourth relationships; and instructions to deploy the real-time model during the wellbore treatment operation.

Implementation #19: The machine-readable media of any one or more of Implementations 14-18, further comprising: instructions to determine a fourth relationship between the one or more controllable variables and an objective function, wherein the one or more controllable variables are related to the first operation parameter via the third relationship; instructions to predict, based on the third and fourth relationships, an optimal first operation parameter that optimizes the objective function; and instructions to determine an optimized controllable variable based on the optimal first operation parameter.

Implementation #20: The machine-readable media of any one or more of Implementations 14-19, wherein the instructions to adjust the wellbore treatment operation comprise: instructions to perform at least part of the wellbore treatment operation with the optimized controllable variable, and wherein the first operation parameter is a treatment pressure of one or more pumps.

As used herein, a phrase referring to “at least one of” a list of items refers to any combination of those items, including single members. As an example, “at least one of: a, b, or c” is intended to cover: a, b, c, a-b, a-c, b-c, and a-b-c. Use of the phrase “at least one of” preceding a list with the conjunction “and” should not be treated as an exclusive list and should not be construed as a list of categories with one item from each category, unless specifically stated otherwise. A clause that recites “at least one of A, B, and C” may be infringed with only one of the listed items, multiple of the listed items, and one or more of the items in the list and another item not listed.

As used herein, the term “or” is inclusive unless otherwise explicitly noted. Thus, the phrase “at least one of A, B, or C” is satisfied by any element from the set {A, B, C} or any combination thereof, including multiples of any element.

The various illustrative logics, logical blocks, modules, circuits, and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described throughout. Whether such functionality is implemented in hardware or software depends upon the particular application and design constraints imposed on the overall system.

The hardware and data processing apparatus used to implement the various illustrative logics, logical blocks, modules and circuits described in connection with the implementations disclosed herein may be implemented or performed with a general purpose single- or multi-chip processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor or any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more implementations, the functions described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, e.g., one or more modules of computer program instructions stored on a computer storage media for execution by, or to control the operation of, a computing device.

If implemented in software, the functions may be stored on or transmitted over as one or more instructions or code on a computer-readable medium. The processes of a method or algorithm disclosed herein may be implemented in a processor-executable instructions which may reside on a computer-readable medium. Computer-readable media includes both computer storage media and communication media including any medium that may be enabled to transfer a computer program from one place to another. Storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-Ray™ disc where disks usually reproduce data magnetically, while discs reproduce data optically with lasers. Combinations also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein but are to be accorded the widest scope consistent with this disclosure, the principles and the novel features disclosed herein.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described as acting in certain combinations and even initially claimed as such, one or more features from a claimed combination may in some cases be excised from the combination, and the claimed combination may be directed to a subcombination or variation of a subcombination.

While operations are depicted in the drawings in a particular order, this should not be understood as requiring that such operations be performed in the particular order shown or in sequential order, or that all illustrated operations be performed, to achieve desirable results. Further, the drawings may schematically depict one more example process in the form of a flow diagram. However, some operations may be omitted and/or other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described should not be understood as requiring such separation in all implementations, and the described program components and systems may generally be integrated together in a single software product or packaged into multiple software products. Additionally, other implementations are within the scope of the following claims. In some cases, the actions recited in the claims may be performed in a different order and still achieve desirable results.

1. A method comprising:
systematically changing a first value of one or more controllable variables used in a wellbore treatment operation;
monitoring a value of a first operation parameter in response to systematically changing the first value of the one or more controllable variables;
building at least a first relationship between the one or more controllable variables, the first operation parameter, and one or more cost functions;
selecting a second value of the one or more controllable variables based on an optimized cost function; and
adjusting the wellbore treatment operation based, at least in part, on the second value of the one or more controllable variables.

2. The method of claim 1, wherein systematically changing the first value of the one or more controllable variables comprises:
altering, during the wellbore treatment operation, a material concentration at a plurality of set points.

3. The method of claim 2, wherein monitoring the value of the first operation parameter in response to systematically changing the value of the one or more controllable variables comprises:
monitoring, during the wellbore treatment operation, changes in the first operation parameter over the plurality of set points.

4. The method of claim 3, further comprising:
determining a second relationship between change in one or more controllable variables and change in the first operation parameter across the plurality of set points;
integrating the second relationship; and
determining, based on the integrating, a third relationship between the first operation parameter and the one or more controllable variables.

5. The method of claim 4, further comprising:
determining a fourth relationship between the one or more controllable variables and an objective function, wherein the one or more controllable variables are related to the first operation parameter via the third relationship;
predicting, based on the third and fourth relationships, an optimal first operation parameter that optimizes the objective function; and
determining an optimized controllable variable based on the optimal first operation parameter.

6. The method of claim 5, further comprising:
generating a real-time model based, at least in part, on the third and fourth relationships; and
deploying the real-time model during the wellbore treatment operation.

7. The method of claim 5, wherein adjusting the wellbore treatment operation comprises:
performing at least part of the wellbore treatment operation with the optimized controllable variable,
wherein the first operation parameter is a treatment pressure of one or more pumps, and
wherein the one or more controllable variables includes an additive concentration.

8. A system comprising:
one or more pumps proximate to the wellbore;
a processor; and
a computer-readable medium having instructions executable by the processor, the instructions including:
instructions to systematically change a first value of one or more controllable variables to be used in a wellbore treatment operation of a wellbore formed in one or more subsurface formations;
instructions to monitor a value of a first operation parameter in response to systematically changing the first value of the one or more controllable variables;
instructions to build at least a first relationship between the one or more controllable variables, the first operation parameter, and one or more cost functions;
instructions to select a second value of the one or more controllable variables based on an optimized cost function; and
instructions to adjust the wellbore treatment operation based, at least in part, on the second value of the one or more controllable variables.

9. The system of claim 8, further comprising:
one or more containers including one or more materials,
wherein the instructions to systematically change the first value of the one or more controllable variables comprise instructions to alter, during the wellbore treatment operation, a material concentration of the one or more materials at a plurality of set points.

10. The system of claim 9, wherein the instructions to monitor the value of the first operation parameter in response to the systematic change of the value of the one or more controllable variables comprise:
instructions to monitor, during the wellbore treatment operation, changes in the first operation parameter over the plurality of set points.

11. The system of claim 10, further comprising:
instructions to determine a second relationship between change in one or more controllable variables and change in the first operation parameter across the plurality of set points;
instructions to integrate the second relationship; and
instructions to determine, based on the integration, a third relationship between the first operation parameter and the one or more controllable variables.

12. The system of claim 11, further comprising:
instructions to determine a fourth relationship between the one or more controllable variables and an objective function, wherein the one or more controllable variables are related to the first operation parameter via the third relationship;
instructions to predict, based on the third and fourth relationships, an optimal first operation parameter that optimizes the objective function; and
instructions to determine an optimized controllable variable based on the optimal first operation parameter.

13. The system of claim 12, wherein the instructions to adjust the wellbore treatment operation comprise:
instructions to perform at least part of the wellbore treatment operation with the optimized controllable variable, and
wherein the first operation parameter is a treatment pressure of the one or more pumps.

14. One or more non-transitory machine-readable media including instructions executable by a processor, the instructions comprising:
instructions to systematically change a first value of one or more controllable variables to be used in a wellbore treatment operation of a wellbore formed in one or more subsurface formations;
instructions to monitor a value of a first operation parameter in response to systematically changing the first value of the one or more controllable variables;
instructions to build at least a first relationship between the one or more controllable variables, the first operation parameter, and one or more cost functions;
instructions to select a second value of the one or more controllable variables based on an optimized cost function; and
instructions to adjust the wellbore treatment operation based, at least in part, on the second value of the one or more controllable variables.

15. The machine-readable media of claim 14, wherein the instructions to systematically change the first value of the one or more controllable variables comprise:
instructions to alter, during the wellbore treatment operation, a material concentration at a plurality of set points.

16. The machine-readable media of claim 15, wherein the instructions to monitor the value of the first operation parameter in response to the systematic change of the value of the one or more controllable variables comprise:
instructions to monitor, during the wellbore treatment operation, changes in the first operation parameter over the plurality of set points.

17. The machine-readable media of claim 16, further comprising:
instructions to determine a second relationship between change in one or more controllable variables and change in the first operation parameter across the plurality of set points;
instructions to integrate the second relationship; and
instructions to determine, based on the integration, a third relationship between the first operation parameter and the one or more controllable variables.

18. The machine-readable media of claim 17, further comprising:
instructions to generate a real-time model based, at least in part, on the third and fourth relationships; and
instructions to deploy the real-time model during the wellbore treatment operation.

19. The machine-readable media of claim 17, further comprising:
instructions to determine a fourth relationship between the one or more controllable variables and an objective function, wherein the one or more controllable variables are related to the first operation parameter via the third relationship;
instructions to predict, based on the third and fourth relationships, an optimal first operation parameter that optimizes the objective function; and
instructions to determine an optimized controllable variable based on the optimal first operation parameter.

20. The machine-readable media of claim 19, wherein the instructions to adjust the wellbore treatment operation comprise:
instructions to perform at least part of the wellbore treatment operation with the optimized controllable variable, and
wherein the first operation parameter is a treatment pressure of one or more pumps.
